(19) United States
(12) Patent Application Publication
(10) Pub. No.: US 2024/0230856 A1
(43) Pub. Date: Jul. 11, 2024

(54) LIGHT RECEIVING ELEMENT, DISTANCE MEASUREMENT MODULE, DISTANCE MEASUREMENT SYSTEM, AND METHOD FOR CONTROLLING LIGHT RECEIVING ELEMENT

(71) Applicant: SONY SEMICONDUCTOR SOLUTIONS CORPORATION, KANAGAWA (JP)

(72) Inventor: YASUNORI TSUKUDA, KANAGAWA (JP)

(21) Appl. No.: 18/245,705

(22) PCT Filed: Aug. 16, 2021
(86) PCT No.: PCT/JP2021/029872

§ 371 Date: Mar. 16, 2023

(30) Foreign Application Priority Data
Oct. 7, 2020 (JP) 2020-169469

(51) Int. Cl. G01S 7/486; G01S 17/08; G01S 17/931; H01L 27/146; H01L 31/107; H03K 17/56

(52) U.S. Cl. CPC G01S 7/486; G01S 17/08; H01L 31/107; H03K 17/56; G01S 17/931; H01L 27/146

(57) ABSTRACT

To improve the distance measurement accuracy in a light receiving element that performs distance measurement on the basis of a light reception timing of reflected light. A charging section (330) causes a constant current to flow between any one terminal of a cathode and an anode of an avalanche photodiode (340) and a predetermined voltage. A source of a source follower transistor (320) is connected to the one terminal of the avalanche photodiode (340). A logic gate (350) outputs an output signal on the basis of a comparison result between a voltage of the one terminal of the avalanche photodiode (340) and a predetermined reference voltage. A source follower cut-off switch (310) opens and closes a path between a drain of the source follower transistor (320) and the predetermined voltage on the basis of the output signal.

### TECHNICAL FIELD

The present technology relates to a light receiving element. Specifically, the present technology relates to a light receiving element that detects the presence or absence of a photon, a distance measurement module, a distance measurement system, and a method for controlling the light receiving element.

### BACKGROUND ART

Conventionally, a distance measurement scheme called a time of flight (ToF) scheme is known in electronic devices having distance measurement functions. The ToF scheme is a scheme of measuring a distance by irradiating an object with irradiation light from an electronic device and obtaining a round-trip time until the irradiation light is reflected and returns to the electronic device. A single-photon avalanche diode (SPAD) is often used to detect the reflected light with respect to the irradiation light. For example, there is proposed a distance measurement device provided with a SPAD, a current source that charges the SPAD, and an active recharge circuit that starts charging the SPAD after a lapse of a certain time from when a cathode voltage of the SPAD drops (see, for example, Patent Document 1).

### CITATION LIST

### Patent Document

Patent Document 1: Japanese Patent Application Laid-Open No. 2020-94849

### SUMMARY OF THE INVENTION

### Problems to be Solved by the Invention

In the above-described conventional technique, the active recharge circuit as well as the current source performs charging, thereby shortening the time from the drop of the cathode voltage to the return to a voltage before the drop. However, when photons are incident during the charging by the active recharge circuit, there is a problem that a waveform of a signal from the SPAD is disturbed to increase an error in distance measurement so that the distance measurement accuracy decreases.

The present technology has been made in view of such circumstances, and an object thereof is to improve the distance measurement accuracy in a light receiving element that performs distance measurement on the basis of a light reception timing of reflected light.

### Solutions to Problems

The present technology has been made to solve the above-described problems, and a first aspect thereof relates to a light receiving element and a method for controlling the same, the light receiving element including: an avalanche photodiode; a charging section that causes a constant current to flow between any one terminal of a cathode and an anode of the avalanche photodiode and a predetermined voltage; a source follower transistor having a source connected to the one terminal; a logic gate that outputs an output signal on the basis of a comparison result between a voltage of the one terminal and a predetermined reference voltage; and a source follower cut-off switch that opens and closes a path between a drain of the source follower transistor and the predetermined voltage on the basis of the output signal. This brings about an effect of improving the distance measurement accuracy.

Furthermore, in the first aspect, the source follower cut-off switch may transition to an open state when the output signal of a predetermined level is output, and transition to a closed state when a predetermined delay time elapses since the transition to the open state, and the source follower transistor may generate a drain current within a period from when the source follower cut-off switch transitions to the closed state to when the voltage of the one terminal becomes a predetermined cut-off voltage. This brings about an effect that the distance measurement accuracy is improved when the illuminance is high.

Furthermore, in the first aspect, a bias voltage within a range from a sum of a threshold voltage of the source follower transistor and the voltage of the one terminal when the source follower cut-off switch transitions from the open state to the closed state to a sum of the reference voltage and the threshold voltage may be applied to a gate of the source follower transistor. This brings about an effect that the drain current is generated within a period from when the source follower cut-off switch transitions to the closed state to when the output signal reaches the predetermined level.

Furthermore, in the first aspect, a voltage limiting transistor that limits an amplitude of a signal input to the logic gate may be further provided. This brings about an effect that a transistor having a small element size can be used.

Furthermore, in the first aspect, an input terminal of the logic gate may be connected to a connection node between the charging section and the voltage limiting transistor. This brings about the effect that the transistor having the small element size can be used.

Furthermore, in the first aspect, an input terminal of the logic gate may be connected to a connection node between the voltage limiting transistor and the avalanche photodiode. This brings about an effect that the area of a current source and the like can be reduced while suppressing an increase in a quench detection time error.

Furthermore, in the first aspect, the predetermined voltage may be applied to a gate of the source follower transistor.

Furthermore, in the first aspect, a distance calculation section that calculates a distance to an object on the basis of a time between a light emission timing of irradiation light from a light emitting source and one timing of falling and rising of the output signal may be further provided. This brings about an effect that the distance to the object is measured.

Furthermore, in the first aspect, the avalanche photodiode, the charging section, the source follower transistor, the logic gate, and the source follower cut-off switch may be provided in each of a plurality of pixels. This brings about an effect that presence or absence of a photon is detected for every pixel.

Furthermore, in the first aspect, the avalanche photodiode may be provided on a predetermined light receiving substrate, and the charging section, the source follower transistor, the logic gate, and the source follower cut-off switch may be provided on a predetermined logic substrate. This brings about to an effect that the circuit scale for each substrate is reduced.

Furthermore, in the first aspect, the avalanche photodiode may be provided on a predetermined light receiving substrate, a part of a read circuit including the source follower transistor and the source follower cut-off switch may be provided on a predetermined high-withstand-voltage substrate, and the rest of the read circuit may be provided on a predetermined logic substrate. This brings about an effect that miniaturization of a pixel is facilitated.

Furthermore, in the first aspect, the charging section may include a current limiting resistor inserted between the predetermined voltage and the one terminal. This brings about an effect that the number of wires is reduced.

Furthermore, in the first aspect, a charging section cut-off switch that opens and closes a path between the charging section and the predetermined voltage on the basis of the output signal may be further provided. This brings about an effect that the constant current from the current source is cut off.

Furthermore, in the first aspect, a pulse shaping circuit that outputs a pulse signal of a first logic level for setting the source follower cut-off switch in the open state over a period until a predetermined delay time elapses since any timing of falling and rising of the output signal may be further provided, and the source follower cut-off switch may transition to the open state in a period in which the pulse signal is at the first logic level level, and transition to the closed state in a period in which the pulse signal is at a second logic level different from the first logic level. This brings about an effect that the drain current of the source follower transistor is generated when the delay time elapses.

Furthermore, in the first aspect, a pulse shaping circuit that outputs a pulse signal of a first logic level for setting the source follower cut-off switch in the closed state over a period of a pulse width when a predetermined delay time elapses since any timing of falling and rising of the output signal may be further provided, and the source follower cut-off switch may transition to the open state in a period in which the pulse signal is at a second logic level different from the first logic level, and transition to the closed state in a period in which the pulse signal is at the first logic level. This brings about an effect that the drain current of the source follower transistor is generated when the delay time elapses.

Furthermore, in the first aspect, the one terminal may be the cathode, the predetermined voltage may be a power supply voltage, and the charging section may supply the constant current to the cathode from the power supply voltage. This brings about an effect that a photon is detected from a decrease in the cathode voltage.

Furthermore, in the first aspect, the one terminal may be the anode, the predetermined voltage may be a read circuit ground, and the charging section may supply the constant current from the anode to the read circuit ground. This brings about an effect that a photon is detected from an increase in the anode voltage.

Furthermore, a second aspect of the present technology is a distance measurement system including: an illumination device that emits irradiation light; and a light receiving element that receives reflected light with respect to the irradiation light, the light receiving element including: an avalanche photodiode; a charging section that causes a constant current to flow between any one terminal of a cathode and an anode of the avalanche photodiode and a predetermined voltage; a source follower transistor having a source connected to the one terminal; a logic gate that outputs an output signal on the basis of a comparison result between a voltage of the one terminal and a predetermined reference voltage; and a source follower cut-off switch that opens and closes a path between a drain of the source follower transistor and the predetermined voltage on the basis of the output signal. This brings about an effect of improving the distance measurement accuracy of the distance measurement system.

Furthermore, a third aspect of the present technology is a distance measurement module including: an avalanche photodiode; a charging section that causes a constant current to flow between any one terminal of a cathode and an anode of the avalanche photodiode and a predetermined voltage; a source follower transistor having a source connected to the one terminal; a logic gate that outputs an output signal on the basis of a comparison result between a voltage of the one terminal and a predetermined reference voltage; a source follower cut-off switch that opens and closes a path between a drain of the source follower transistor and the predetermined voltage on the basis of the output signal; and a signal processing section that processes the output signal. This brings about an effect of improving the distance measurement accuracy of the distance measurement module.

### BRIEF DESCRIPTION OF DRAWINGS

FIG. 1 is a block diagram depicting a configuration example of a distance measurement module in a first embodiment of the present technology.

FIG. 2 is a block diagram depicting a configuration example of a solid-state imaging element in the first embodiment of the present technology.

FIG. 3 is a circuit diagram depicting a configuration example of a pixel in the first embodiment of the present technology.

FIG. 4 is a circuit diagram depicting an implementation example of the pixel in the first embodiment of the present technology.

FIG. 5 is a block diagram depicting a configuration example of a signal processing section in the first embodiment of the present technology.

FIG. 6 is a block diagram depicting another configuration example of the signal processing section in the first embodiment of the present technology.

FIG. 7 is a timing chart depicting an example of operation of the solid-state imaging element during a distance measurement mode in the first embodiment of the present technology.

FIG. 8 is a timing chart depicting an example of operation of the solid-state imaging element when a transition is made from a standby mode to the distance measurement mode in the first embodiment of the present technology.

FIG. 9 is a flowchart depicting an example of operation of the distance measurement module in the first embodiment of the present technology.

FIG. 10 is a circuit diagram depicting a configuration example of a pixel in a second embodiment of the present technology.

FIG. 11 is a circuit diagram depicting a configuration example of a pixel in a third embodiment of the present technology.

FIG. 12 is a circuit diagram depicting a configuration example of a pixel in a fourth embodiment of the present technology.

FIG. 13 is a circuit diagram depicting a configuration example of a pixel in a modified example of the fourth embodiment of the present technology.

FIG. 14 is a timing chart depicting an example of operation of a solid-state imaging element during a distance measurement mode in a fifth embodiment of the present technology.

FIG. 15 is a timing chart depicting an example of operation of the solid-state imaging element when a transition is made from a standby mode to the distance measurement mode in the fifth embodiment of the present technology.

FIG. 16 is a circuit diagram depicting a configuration example of a pixel in a sixth embodiment of the present technology.

FIG. 17 is a circuit diagram depicting a configuration example of a pixel in a seventh embodiment of the present technology.

FIG. 18 is a circuit diagram illustrating a configuration example of a pixel in a case where the fourth embodiment is applied to the seventh embodiment of the present technology.

FIG. 19 is a circuit diagram illustrating a configuration example of a pixel in a case where the modified example of the fourth embodiment is applied to the seventh embodiment of the present technology.

FIG. 20 is a circuit diagram depicting a configuration example of a pixel in an eighth embodiment of the present technology.

FIG. 21 is a block diagram depicting an example of a schematic configuration of a vehicle control system.

FIG. 22 is an explanatory diagram depicting an example of an installation position of an imaging section.

### MODE FOR CARRYING OUT THE INVENTION

Hereinafter, modes for carrying out the present technology (hereinafter, referred to as embodiments) will be described. The description will be given in the following order.
1. First Embodiment (Example of Providing Source Follower Transistor)
2. Second Embodiment (Example of Providing Source Follower Transistor and Resistor)
3. Third Embodiment (Example of Providing Source Follower Transistor and Cutting off Constant Current)
4. Fourth Embodiment (Example of Providing Source Follower Transistor and Limiting Amplitude)
5. Fifth Embodiment (Example of Providing Source Follower Transistor and Generating Low-Level Pulse Signal)
6. Sixth Embodiment (Example of Providing Source Follower Transistor and Applying Power Supply Voltage to Gate Thereof)
7. Seventh Embodiment (Example of Providing Source Follower Transistor and Arranging Elements in Pixel on Three Substrates)
8. Eighth Embodiment (Example of Providing Source Follower Transistor and Reversing Connection Destinations of Anode and Cathode of SPAD)
9. Example of Application to Mobile Body

### 1. First Embodiment

### [Configuration Example of Distance Measurement Module]

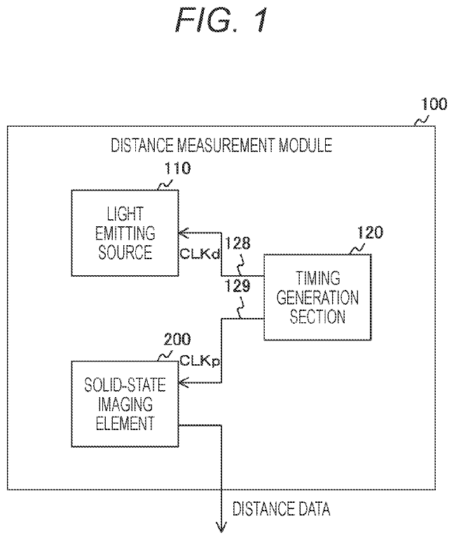

FIG. 1 is a block diagram depicting a configuration example of a distance measurement module 100 in a first embodiment of the present technology. The distance measurement module 100 measures a distance to an object, and includes a light emitting source 110, a timing generation section 120, and a solid-state imaging element 200. The distance measurement module 100 is mounted on a smartphone, a personal computer, a vehicle-mounted device, or the like, and is used to measure a distance. Note that the system provided with the distance measurement module 100 is an example of a distance measurement system described in the claims.

The timing generation section 120 generates a timing signal for causing the light emitting source 110 and the solid-state imaging element 200 to operate in synchronization. The timing generation section 120 generates a clock signal CLKp having a predetermined frequency (100 megahertz to 10 gigahertz or the like) as the timing signal, and supplies the clock signal CLKp to the solid-state imaging element 200 via a signal line 129. Furthermore, the timing generation section 120 supplies a clock signal CLKd generated in synchronization with the clock signal CLKp to the light emitting source 110 via a signal line 128. A frequency of the clock signal CLKd is 1/N (N is an integer) of that of the clock signal CLKp.

The light emitting source 110 supplies intermittent light as irradiation light in synchronization with the clock signal CLKd from the timing generation section 120. For example, near-infrared light or the like is used as the irradiation light. Note that the light emitting source 110 is an example of an irradiation device described in the claims.

The solid-state imaging element 200 receives reflected light with respect to the irradiation light, and measures a round-trip time from a light emission timing indicated by the clock signal CLKd to a timing at which the reflected light is received. The solid-state imaging element 200 calculates a distance to an object from the round-trip time, and generates and outputs distance data indicating the distance. Note that the solid-state imaging element 200 is an example of a light receiving element described in the claims.

### [Configuration Example of Solid-State Imaging Element]

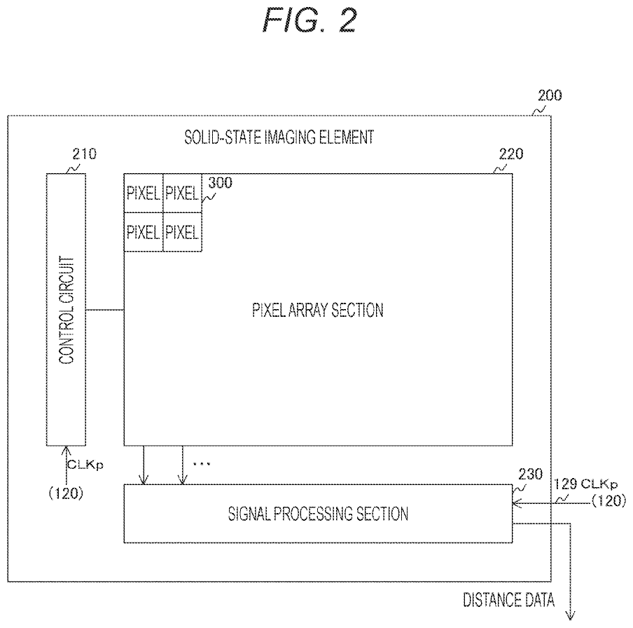

FIG. 2 is a block diagram depicting a configuration example of the solid-state imaging element 200 in the first embodiment of the present technology. The solid-state imaging element 200 includes a control circuit 210, a pixel array section 220, and a signal processing section 230. In the pixel array section 220, a plurality of pixels 300 is arrayed in a two-dimensional lattice pattern.

The control circuit 210 controls each of the pixels 300 in the pixel array section 220 on the basis of the clock signal CLKp from the timing generation section 120.

The signal processing section 230 measures the round-trip time for every pixel 300 on the basis of a signal from the pixel 300 and the clock signal CLKp, and calculates a distance. The signal processing section 230 generates distance data indicating the distance for every pixel group corresponding to a distance measurement point and outputs them to the outside. Note that the signal processing section 230 may be arranged inside the pixel array section 220 or may be arranged outside the pixel array section 220.

### [Configuration Example of Pixel]

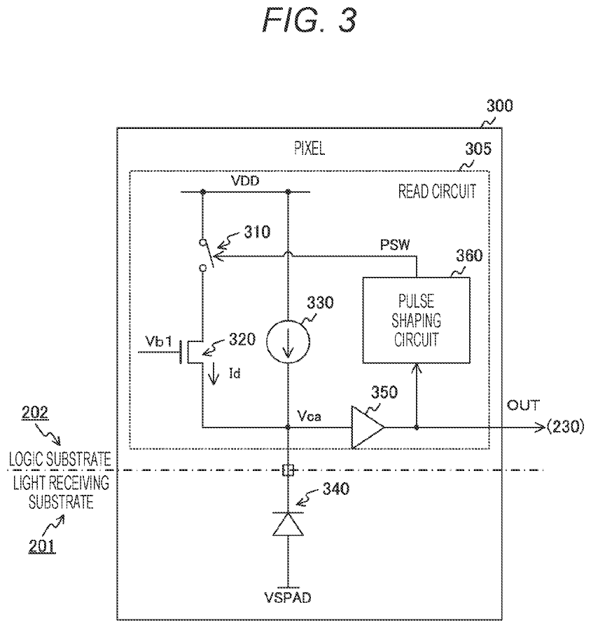

FIG. 3 is a sectional view and a circuit diagram depicting a configuration example of the pixel 300 in the first embodiment of the present technology. The pixel 300 includes a SPAD 340 and a read circuit 305. The SPAD 340 is arranged on a light receiving substrate 201. On the other hand, circuits other than the SPAD 340, that is, the read circuit 305, the control circuit 210, and the signal processing section 230 (not illustrated) are arranged on a logic substrate 202 stacked on the light receiving substrate 201. Since only the SPAD 340 is arranged on the light receiving substrate 201, an aperture ratio of the SPAD 340 can be maximized, and the light reception performance can be improved. However, the capacitance of the pixel 300 increases, and thus, a charging speed decreases accordingly.

The light receiving substrate 201 and the logic substrate 202 are electrically connected via a connecting section such as a via. Note that the connection can also be made by a Cu—Cu bonding or a bump other than the via.

The read circuit 305 includes a source follower (SF) cut-off switch 310, a source follower transistor 320, a current source 330, an amplifier 350, and a pulse shaping circuit 360. As the source follower transistor 320, for example, an n-channel metal oxide semiconductor (nMOS) transistor is used.

The current source 330 is inserted between a power supply voltage VDD and a cathode of the SPAD 340. An anode of the SPAD 340 is connected to a node of a predetermined negative bias VSPAD. Furthermore, the SF cut-off switch 310 and the source follower transistor 320 are connected in series between the power supply voltage VDD and the cathode of the SPAD 340. Furthermore, an input terminal of the amplifier 350 is connected to the cathode of the SPAD 340, and an output terminal of the amplifier 350 is connected to the pulse shaping circuit 360 and the signal processing section 230.

The SPAD 340 generates a charge (an electron and the like) by photoelectric conversion with respect to incident light, performs avalanche multiplication, and outputs the resultant from the cathode. A reverse bias having a larger absolute value than a breakdown voltage at the time of avalanche breakdown is applied between the anode and the cathode of the SPAD 340. A difference between the reverse bias and the breakdown voltage is called an excess bias. When a photon is incident, a cathode voltage Vca of the SPAD 340 drops by the amount corresponding to the excess bias, and the cathode voltage at this time is set as a bottom potential V_{btm}. Note that the SPAD 340 is an example of an avalanche photodiode described in the claims.

The current source 330 causes a constant current to flow in a path from the power supply voltage VDD to the cathode of the SPAD 340. Note that the current source 330 is an example of a charging section described in the claims.

The amplifier 350 outputs an output signal OUT on the basis of a comparison result between the cathode voltage Vca of the SPAD 340 and a predetermined reference voltage V_{ref}. A low-level output signal OUT is output in a case where the cathode voltage Vca is equal to or lower than the reference voltage V_{ref}, and a high-level output signal OUT is output in a case where the cathode voltage Vca is higher than the reference voltage V_{ref}.

The pulse shaping circuit 360 generates a pulse signal PSW on the basis of the output signal OUT and supplies the pulse signal PSW to the SF cut-off switch 310. For example, the pulse shaping circuit 360 generates a high-level pulse signal PSW over a period until a predetermined delay time elapses since falling of the output signal OUT. In a delay period, for example, a value that substantially coincides with a time from when an output of the amplifier 350 is inverted by the incidence of the photon to when the cathode voltage Vca reaches the bottom potential V_{btm} is set.

The SF cut-off switch 310 opens and closes a path between a drain of the source follower transistor 320 and the power supply voltage VDD according to the pulse signal PSW. For example, the SF cut-off switch 310 transitions to an open state within a period in which the pulse signal PSW is at the high level, and transitions to a closed state within a period in which the pulse signal PSW is at a low level. Note that the SF cut-off switch 310 is an example of a source follower cut-off switch described in the claims.

A predetermined bias voltage Vb1 is applied to a gate of the source follower transistor 320. A method for setting the bias voltage Vb1 will be described later.

With the above-described connection configuration, when a photon is incident on the pixel 300, the SPAD 340 performs avalanche multiplication on the charge obtained by photoelectrically converting the photon to generate a photocurrent. The cathode voltage Vca of the SPAD 340 drops according to the photocurrent. Then, when the cathode voltage Vca becomes equal to or lower than the reference voltage V_{ref} of the amplifier 350, the amplifier 350 outputs the low-level output signal OUT. Therefore, the incidence of the photon is detected.

Furthermore, the pulse shaping circuit 360 generates the high-level pulse signal PSW over the period until the delay time elapses since the falling of the output signal OUT. The high-level pulse signal PSW causes the SF cut-off switch 310 to transition to the open state.

Then, when the delay time elapses since the falling of the output signal OUT, the pulse signal PSW becomes the low level, and the SF cut-off switch 310 transitions to the closed state. At this time, the source follower transistor 320 is turned on, and generates a drain current Id according to the bias voltage Vb1. Furthermore, since the cathode voltage Vca has reached the bottom potential V_{btm}, the SPAD 340 is charged by the constant current from the current source 330 and the drain current Id, and the cathode voltage Vca increases. However, before the cathode voltage Vca reaches the reference voltage V_{ref} of the amplifier 350, the source follower transistor 320 is turned off.

Here, a value satisfying the following formulas is set as the bias voltage Vb1.

$${V}_{btm} < Vb 1 - {V}_{thn} \qquad Formula 1$$

$${V}_{ref} > Vb 1 - {V}_{thn} \qquad Formula 2$$

In the above formulas, Vₜₕₙ is a threshold voltage of the source follower transistor 320.

Due to the bias voltage Vb1 satisfying Formula 1, the source follower transistor 320 is turned on when the SF cut-off switch 310 on the drain side transitions to the closed state. Furthermore, due to the bias voltage Vb1 satisfying Formula 2, the source follower transistor 320 is turned off before the cathode voltage Vca reaches the reference voltage V_{ref} of the amplifier 350.

When Formulas 1 and 2 are summarized, the following formula is obtained.

$${V}_{btm} + {V}_{thn} < V b 1 < {V}_{r e f} + {V}_{thn}$$

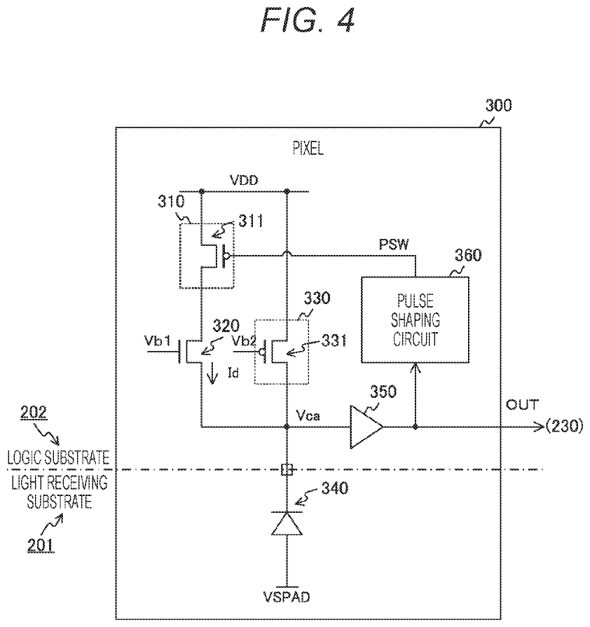

FIG. 4 is a circuit diagram depicting an implementation example of the pixel 300 in the first embodiment of the present technology. For example, a pMOS transistor 311 is used as the SF cut-off switch 310. Furthermore, a pMOS transistor 331 having a gate to which a bias voltage Vb2 is applied is used as the current source 330.

Note that an nMOS transistor can also be used as the SF cut-off switch 310. In this case, it is only required to reverse the polarity of the pulse signal PSW.

Furthermore, an inverter can be used instead of the amplifier 350. In this case, it is only required to reverse the polarity of the pulse signal PSW or to use the nMOS transistor as the SF cut-off switch 310. Note that the amplifier 350 is an example of a logic gate described in the claims.

### [Configuration Example of Signal Processing Section]

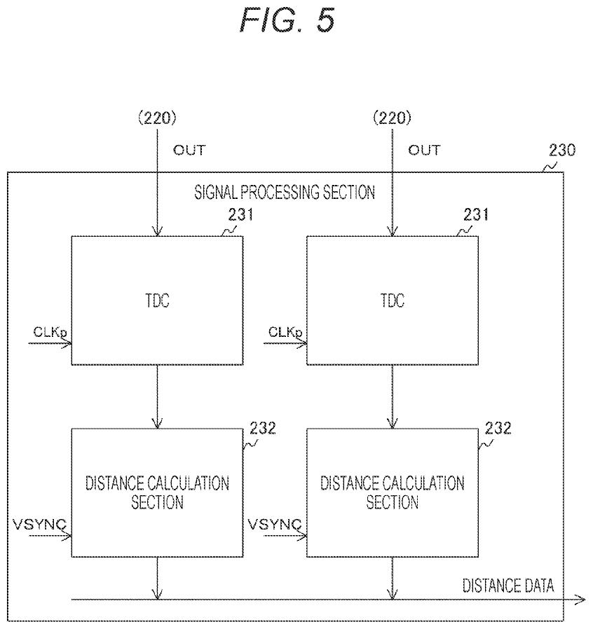

FIG. 5 is a block diagram depicting a configuration example of the signal processing section 230 in the first embodiment of the present technology. The signal processing section 230 includes a time-to-digital converter (TDC) 231 and a distance calculation section 232 for every column or every predetermined number of pixels.

The TDC 231 measures a time from a light emission timing indicated by the clock signal CLKp to falling (that is, a light reception timing) of the output signal OUT from a corresponding column. The TDC 231 supplies a digital signal indicating the measured time to the distance calculation section 232.

The distance calculation section 232 accumulates a histogram for each result of the TDC. The distance calculation section 232 outputs a histogram every cycle of a frequency lower than that of the clock signal CLKp, the histogram being measured by the TDC 231 within the cycle. Note that the distance calculation section 232 may calculate a distance D using the following formula and output distance data indicating the distance D.

$$D = c \times dt / 2$$

In the above formula, c is the speed of light, and a unit thereof is meters per second (m/s). Furthermore, a unit of the distance D is, for example, meter (m), and a unit of a round-trip time dt is, for example, second (s).

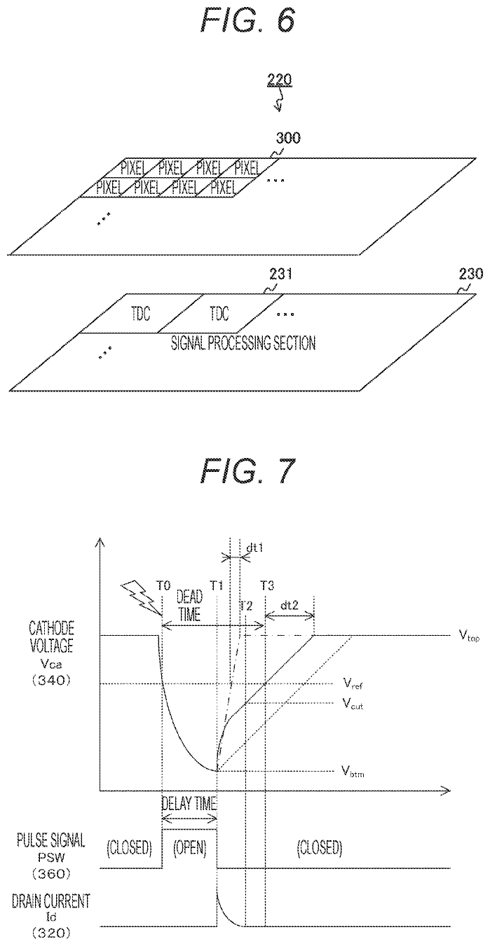

Note that the signal processing section 230 can also be arranged in the pixel array section 220 as illustrated in FIG. 6. In this case, the TDC 231 is arranged for every predetermined number of (for example, 4) pixels 300 on a lower side thereof. The distance calculation section 232 is omitted in this drawing.

FIG. 7 is a timing chart depicting an example of operation of the solid-state imaging element during a distance measurement mode in the first embodiment of the present technology. When a photon is incident immediately before a timing T0, the cathode voltage Vca starts to fall from a top potential Vₜₒₚ in the initial state, and becomes equal to or lower than the threshold of the amplifier 350 at the timing T0. Therefore, the output signal OUT of the amplifier 350 becomes the low level.

The cathode voltage Vca reaches the bottom potential V_{btm} at a timing T1 when the delay time has elapsed since the timing T0. Furthermore, the pulse shaping circuit 360 outputs the high-level pulse signal PSW within a period between the timings TO and T1. Within this period, the SF cut-off switch 310 transitions to the open state.

When the pulse signal PSW becomes the low level at the timing T1, the SF cut-off switch 310 transitions to the closed state, and the source follower transistor 320 supplies the drain current Id. After the timing T1, the SPAD 340 is charged by the constant current from the current source 330 and the drain current Id, and the cathode voltage Vca increases. In this manner, the charging with a charging current larger than the constant current will be hereinafter referred to as “rapid charging”.

Then, at a timing T2 before a timing T3 at which the cathode voltage Vca reaches the reference voltage V_{ref}, the cathode voltage Vca reaches a cut-off voltage V_{cut}, and the source follower transistor 320 is turned off. Therefore, the rapid charging is stopped. Here, the cut-off voltage V_{cut} corresponds to the right side of Formula 2, that is, a difference between the bias voltage Vb1 and the threshold voltage Vₜₕₙ.

At the timing T3, the output signal OUT becomes the high level, and incidence of the next photon can be detected. During a period between the timings T1 and T3, it is difficult for the pixel 300 to react to the incidence of the photon, and this period is called a dead time. When dt2 has elapsed since the timing T3, the cathode voltage Vca returns to the original top potential Vₜₒₚ, and the charging ends.

Here, a pixel having a configuration in which the source follower transistor 320 is not provided and a path between the power supply voltage VDD and the cathode of the SPAD 340 is open and closed by a switch similar to the SF cut-off switch 310 is assumed as a first comparative example.

Since the source follower transistor 320 is not turned off at the timing T2 in the first comparative example, the rapid charging continues. Therefore, a rising speed of the cathode voltage Vca is faster than that in the case where the source follower transistor 320 is provided. A constant chain line in the drawing indicates fluctuation of the cathode voltage in the first comparative example.

In the first comparative example, the dead time is shorter than that in the case where the source follower transistor 320 is provided, but there is a possibility that an error occurs in distance data at the time of distance measurement. For example, the charging current is larger than the constant current in a period dt1 from when the cathode voltage Vca exceeds the reference voltage V_{ref} by charging to when the charging ends. Therefore, in a case where a photon is incident within the period dt1, a quench waveform is blunted, and time to quench is longer than that in the case where the source follower transistor 320 is provided. As a result, the quench is observed at a timing different from the original timing, and the error in the distance data increases.

On the other hand, in the case where the source follower transistor 320 is provided, the drain current Id of the source follower transistor 320 stops before the cathode voltage Vca reaches the reference voltage V_{ref} (that is, the output signal OUT becomes the low level). Therefore, charging is performed with the constant current in the period dt2 from when the cathode voltage Vca exceeds the reference voltage V_{ref} to when the charging ends. Therefore, in a case where a photon is incident within this period dt2, the time to quench is shorter than that in the first comparative example, and the error in the distance data is reduced.

In particular, a photon is often incident in the periods dt1 and dt2 immediately after the dead time when the illuminance is high. Therefore, the distance measurement accuracy can be improved by providing the source follower transistor 320 when the illuminance is high.

Next, a pixel having a configuration in which both the SF cut-off switch 310 and the source follower transistor 320 are not provided is assumed as a second comparative example. In the second comparative example, charging is performed only by the constant current from the current source 330, and the rapid charging is not performed. Therefore, a rising speed of the cathode voltage Vca is slower than that in the case where the SF cut-off switch 310 and the source follower transistor 320 are provided. A dotted line in the drawing indicates fluctuation of the cathode voltage in the second comparative example. In the second comparative example, the dead time becomes long.

On the other hand, in the case where the SF cut-off switch 310 and the source follower transistor 320 are provided, the rising speed of the cathode voltage Vca increases since the drain current Id is further supplied. Therefore, the dead time can be shortened as compared with the second comparative example.

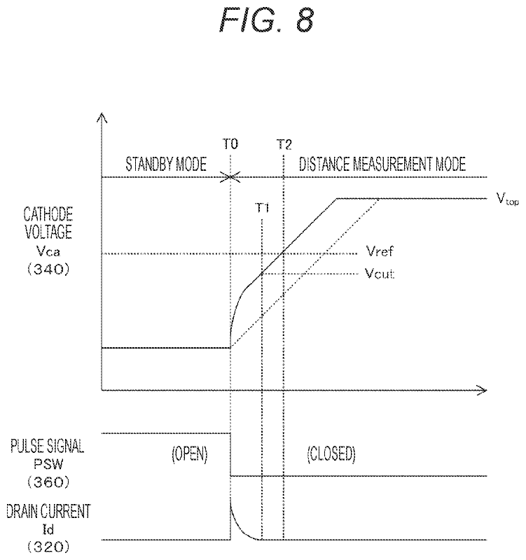

FIG. 8 is a timing chart depicting an example of operation of the solid-state imaging element when a transition is made from a standby mode to the distance measurement mode in the first embodiment of the present technology. Here, the standby mode is a mode in which a light detection operation of the predetermined pixel 300 is set to be invalid. On the other hand, the distance measurement mode is a mode in which the light detection operation of the predetermined pixel 300 is set to be valid. In the standby mode, a pulse signal PSW is set to the high level.

When the distance measurement module 100 transitions from the standby mode to the distance measurement mode at a timing T0, the control circuit 210 controls the pulse shaping circuit 360 in the pixel 300 to output the low-level pulse signal PSW.

When the pulse signal PSW becomes the low level at the timing T0, the SF cut-off switch 310 transitions to the closed state, and the source follower transistor 320 supplies the drain current Id. After a timing T1, the SPAD 340 is rapidly charged by the constant current from the current source 330 and the drain current Id, and the cathode voltage Vca increases.

Then, at the timing T1 before a timing T2 when the cathode voltage Vca reaches the reference voltage V_{ref}, the cathode voltage Vca reaches the cut-off voltage V_{cut}, and the source follower transistor 320 is turned off.

Since the rapid charging is performed in the case where the SF cut-off switch 310 and the source follower transistor 320 are provided, the rising speed of the cathode voltage Vca is faster than that in the second comparative example in which the SF cut-off switch and the source follower transistor are not provided. Therefore, it is possible to shorten the time until the cathode voltage Vca returns and distance measurement becomes possible since the transition to the distance measurement mode. As a result, the shortest measurement distance can be made shorter than that in the second comparative example.

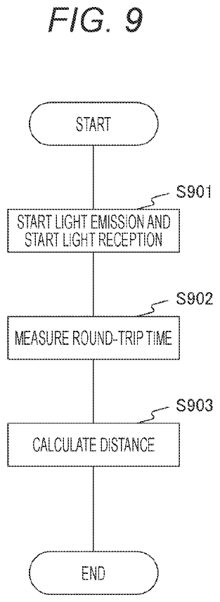

FIG. 9 is a flowchart depicting an example of operation of the distance measurement module 100 in the first embodiment of the present technology. This operation is started when a predetermined application configured to perform distance measurement is executed.

The distance measurement module 100 starts emission of irradiation light and reception of reflected light (step S901). Furthermore, the distance measurement module 100 measures a round-trip time (step S902) and calculates a distance to an object (step S903). After step S903, the distance measurement module 100 ends the operation for distance measurement.

In this manner, in the first embodiment of the present technology, the source follower transistor 320 supplies the drain current in a period from when the SF cut-off switch 310 transitions to the closed state to when the cathode voltage Vca reaches the cut-off voltage V_{cut}. Therefore, the charging current from when the output signal OUT of the pixel 300 becomes the high level to when the charging ends decreases, and the error in the distance data caused by a large charging current within the period can be reduced.

### 2. Second Embodiment

Although the SPAD 340 is charged by the current source 330 in the first embodiment described above, in this configuration, a wire for supplying the bias voltage Vb2 to the current source 330 is required for every pixel, and there is a possibility that it becomes difficult to increase the number of pixels. The solid-state imaging element 200 of a second embodiment is different from that of the first embodiment in that a resistor is provided instead of the current source 330 and the number of wires is reduced.

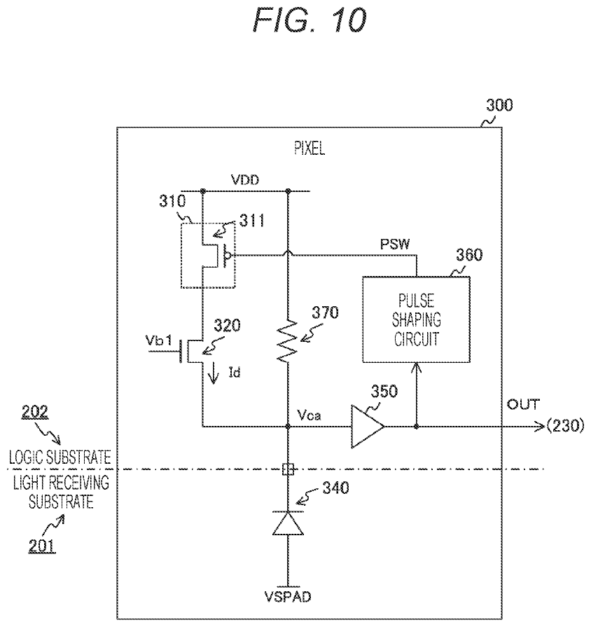

FIG. 10 is a circuit diagram depicting a configuration example of the pixel 300 in the second embodiment of the present technology. The pixel 300 of the second embodiment is different from that of the first embodiment in that a current limiting resistor 370 is arranged instead of the current source 330. The current limiting resistor 370 is inserted between the power supply voltage VDD and a cathode of the SPAD 340. Note that the current limiting resistor 370 is an example of a charging section described in the claims.

Since the current limiting resistor 370 is provided instead of the current source 330, the bias voltage Vb2 becomes unnecessary, and a wire for supplying the voltage can be reduced.

In this manner, the wire for supplying the bias voltage Vb2 can be reduced since the current limiting resistor 370 is provided between the power supply voltage VDD and the cathode of the SPAD 340 according to the second embodiment of the present technology.

### 3. Third Embodiment

In the first embodiment described above, it takes time to settlement of the bias voltage Vb2, and thus, it is difficult to shorten a period until photon detection becomes possible since the transition to the distance measurement mode to enable the pixel. The solid-state imaging element 200 of a third embodiment is different from that of the first embodiment in that a current source cut-off switch 380 is added.

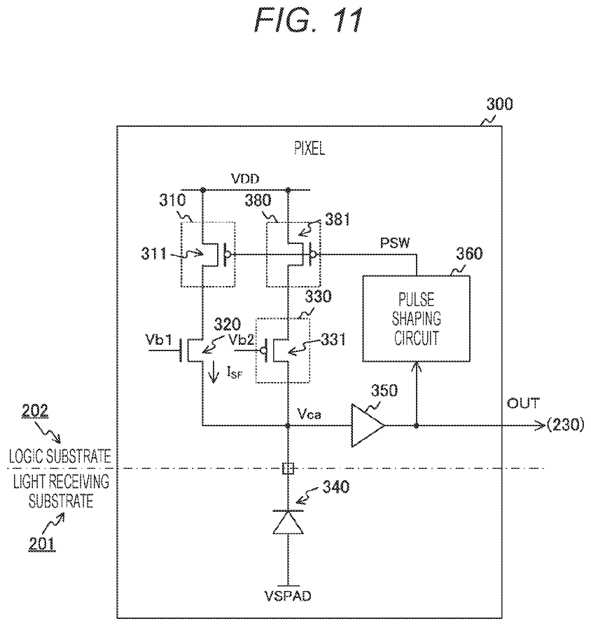

FIG. 11 is a circuit diagram depicting a configuration example of the pixel 300 in the third embodiment of the present technology. The pixel 300 of the third embodiment is different from that of the first embodiment in that the current source cut-off switch 380 is further provided.

The current source cut-off switch 380 opens and closes a path between the power supply voltage VDD and the current source 330 according to the pulse signal PSW. For example, a pMOS transistor 381 is used as the current source cut-off switch 380. Note that the current source cut-off switch 380 is an example of a charging section cut-off switch described in the claims. Furthermore, the current source cut-off switch 380 and the current source 330 are arranged respectively on a power supply side and on a ground side, but conversely, the current source cut-off switch 380 and the current source 330 may be arranged respectively on the ground side and on the power supply side.

The current source cut-off switch 380 cuts off a constant current of the current source 330 during a period in which the pulse signal PSW is at a high level. Therefore, for example, the solid-state imaging element 200 can start the supply of the bias voltage Vb2 in advance before a transition from a standby mode to a distance measurement mode, and can transition to the distance measurement mode to enable the pixel 300 after the bias voltage Vb2 settles. Therefore, it is possible to shorten the time until the photon detection becomes possible when the transition is made from the standby mode to the distance measurement mode.

Note that the second embodiment can be applied to the third embodiment.

In this manner, it is possible to start rapid charging without waiting for the settlement of the bias voltage Vb2 and shorten the time until the photon detection becomes possible since the transition to the distance measurement mode since the current source cut-off switch 380 cuts off the constant current according to the third embodiment of the present technology.

### 4. Fourth Embodiment

In the first embodiment described above, the amplifier 350 outputs the output signal OUT, but it may be difficult to reduce a size of a transistor after the amplifier 350. The solid-state imaging element 200 of a fourth embodiment is different from that of the first embodiment in that a transistor that limits an amplitude is added.

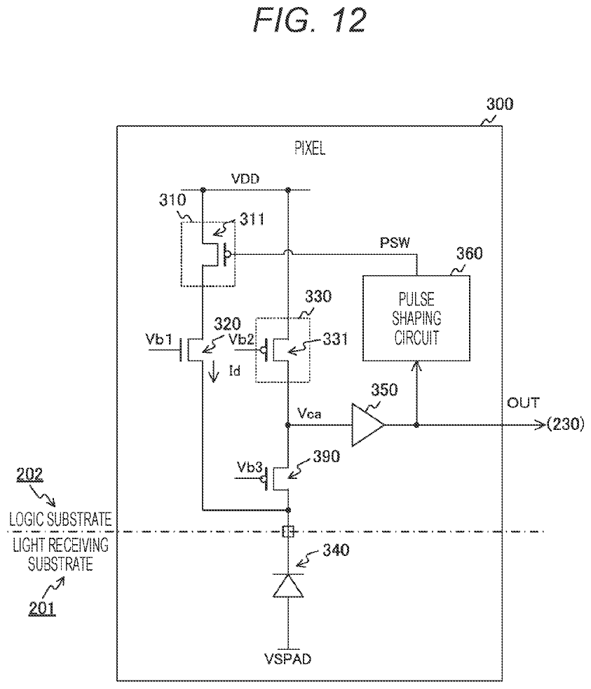

FIG. 12 is a circuit diagram depicting a configuration example of the pixel 300 in the fourth embodiment of the present technology. The pixel 300 of the fourth embodiment is different from that of the first embodiment in that a voltage limiting transistor 390 is further provided.

For example, a pMOS transistor is used as the voltage limiting transistor 390. The voltage limiting transistor 390 is inserted between the current source 330 and the SPAD 340. A bias voltage Vb3 is applied to a gate of the voltage limiting transistor 390. Furthermore, a connection node between the current source 330 and the voltage limiting transistor 390 is connected to an input terminal of the amplifier 350.

The voltage limiting transistor 390 limits an amplitude of an input signal of the current source 330 and the connection node of the voltage limiting transistor 390, that is, the amplifier 350. For example, a value satisfying the following formula is set as the bias voltage Vb3.

$$Vb 3 > VDD - ( V 0 + V 1 ) \qquad Formula 3$$

In the above formula, V0 is a withstand voltage of a thin film transistor. V1 is a voltage between the gate and a source of the voltage limiting transistor 390.

The bias voltage Vb3 satisfying Formula 3 can reduce the amplitude of the input signal of the amplifier 350 to be less than an excess bias of the SAPD 340. Therefore, a transistor having a small element size, such as the thin film transistor, can be used as the transistor after the amplifier 350.

Note that the second and third embodiments can be applied to the fourth embodiment.

In this manner, the element size of the transistor after the amplifier 350 can be reduced since the voltage limiting transistor 390 limits the amplitude of the input signal of the amplifier 350 according to the fourth embodiment of the present technology.

### Modified Example

In the above-described fourth embodiment, the connection node between the current source 330 and the voltage limiting transistor 390 is connected to the input terminal of the amplifier 350. In this configuration, a circuit including the amplifier 350 can be thinned so that the area can be reduced, but a slew rate decreases as an amplitude of the cathode voltage Vca of the connection node decreases. As a result, there is a disadvantage that a quench detection time error due to manufacturing variations of a threshold of the amplifier 350 increases. The solid-state imaging element 200 of a fourth modified example is different from that of the fourth embodiment in that a cathode of the SPAD 340 is directly connected to an input terminal of the amplifier 350.

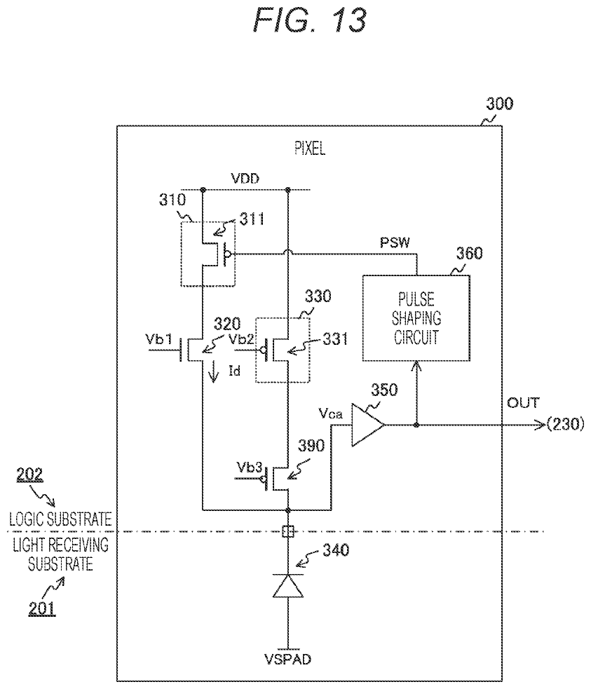

FIG. 13 is a circuit diagram depicting a configuration example of the pixel 300 in the modified example of the fourth embodiment of the present technology. The pixel 300 in the modified example of the fourth embodiment is different from that of the fourth embodiment in that the cathode of the SPAD 340 is connected to the input terminal of the amplifier 350. In the drawing, it is possible to reduce the area of the current source 330 and the like while suppressing the increase in the quench detection time error by monitoring a voltage of the cathode without voltage limitation.

In this manner, it is possible to reduce the area of the current source 330 and the like while suppressing the increase in the quench detection time error since the cathode of the SPAD 340 is connected to the input terminal of the amplifier 350 in the modified example of the fourth embodiment of the present technology.

### 5. Fifth Embodiment

In the first embodiment described above, the pulse shaping circuit 360 generates the high-level pulse signal PSW until the delay time elapses since the falling of the output signal OUT. In this configuration, however, the quench may be inhibited by the charging current at the time of electron multiplication of the SPAD 340. The pixel 300 in a fifth embodiment is different from that in the first embodiment in that the low-level pulse signal PSW is generated when a delay time has elapsed.

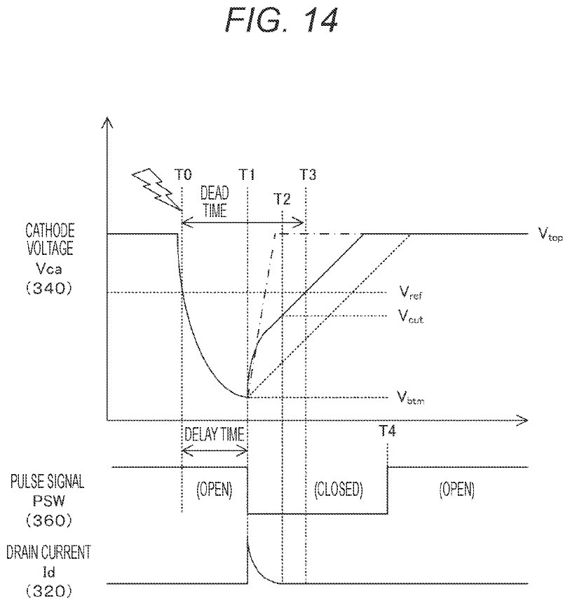

FIG. 14 is a timing chart depicting an example of operation of the solid-state imaging element 200 during a distance measurement mode in the fifth embodiment of the present technology.

At a timing T1 when the delay time has elapsed from a timing T0 when the cathode voltage Vca becomes less than the reference voltage V_{ref}, the pulse shaping circuit 360 of the fifth embodiment generates the low-level pulse signal PSW having a predetermined pulse width. In the drawing, a period from the timing T1 to a timing T4 corresponds to the pulse width. As illustrated in the drawing, the SF cut-off switch 310 is set to the open state in a period from a light incidence timing to the timing T0. This control can prevent quench from being inhibited by a charging current from the source follower transistor 320 at the time of electron multiplication of the SPAD 340 and can shorten the time required for the quench.

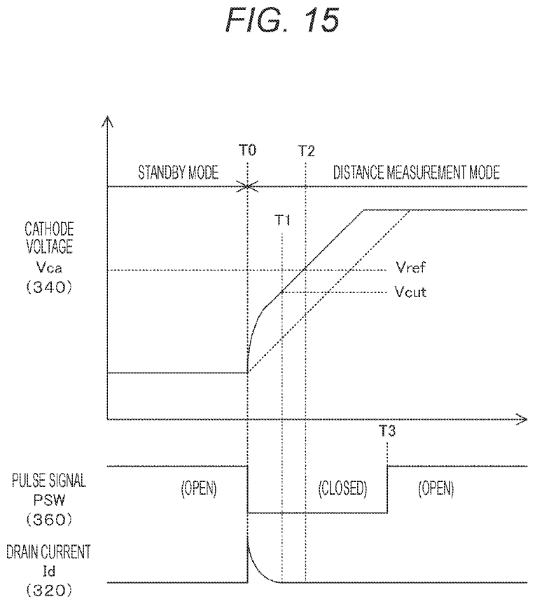

FIG. 15 is a timing chart depicting an example of operation of the solid-state imaging element when a transition is made from a standby mode to the distance measurement mode in the fifth embodiment of the present technology.

When the distance measurement module 100 transitions from the standby mode to the distance measurement mode at a timing TO, the control circuit 210 controls the pulse shaping circuit 360 in the pixel 300 to output the low-level pulse signal PSW having the predetermined pulse width. In the drawing, a period from the timing T0 to a timing T3 corresponds to the pulse width.

Note that each of the second to fourth embodiments can also be applied to the fifth embodiment.

In this manner, since the pulse shaping circuit 360 generates the low-level pulse signal PSW having a predetermined pulse width at the timing when the delay time has elapsed in the fifth embodiment of the present technology. Therefore, it is possible to prevent the quench from being inhibited by the charging current from the source follower transistor 320 at the time of electron multiplication of the SPAD 340 and to shorten the time required for the quench.

### 6. Sixth Embodiment

Although the bias voltage Vb1 is applied to the gate of the source follower transistor 320 in the first embodiment described above, in this configuration, a wire for supplying the bias voltage Vb1 is required for every pixel, and there is a possibility that it is difficult to increase the number of pixels. The solid-state imaging element 200 of a sixth embodiment is different from that of the first embodiment in that the number of wires is reduced by applying the power supply voltage VDD to a gate of the source follower transistor 320.

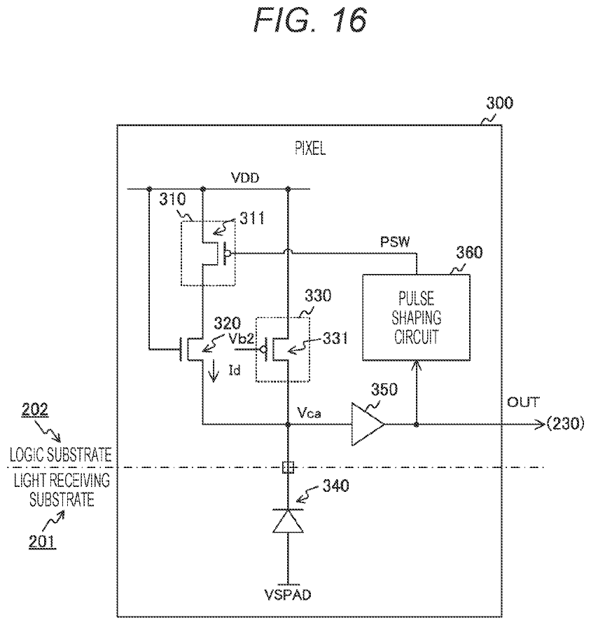

FIG. 16 is a circuit diagram depicting a configuration example of the pixel 300 in the sixth embodiment of the present technology. The pixel 300 of the sixth embodiment is different from that of the first embodiment in that the power supply voltage VDD is applied to the gate of the source follower transistor 320. Therefore, the bias voltage Vb1 becomes unnecessary, and a wire for supplying the bias voltage Vb1 can be reduced. Furthermore, it is assumed that the power supply voltage VDD satisfies the following formula.

$${V}_{btm} + {V}_{thn} < VDD < {V}_{r e f} + {V}_{thn}$$

Note that each of the second to fifth embodiments can also be applied to the sixth embodiment.

In this manner, since the power supply voltage VDD is applied to the gate of the source follower transistor 320 in the sixth embodiment of the present technology, the bias voltage Vb1 becomes unnecessary so that the wire for supplying the bias voltage Vb1 can be reduced.

### 7. Seventh Embodiment

Although the circuits in the solid-state imaging element 200 are dispersedly arranged on the light receiving substrate 201 and the logic substrate 202 in the first embodiment described above, in this configuration, there is a possibility that optimization of a process of the logic substrate 202 is difficult. The solid-state imaging element 200 of a seventh embodiment is different from that of the first embodiment in that circuits in the solid-state imaging element 200 are dispersedly arranged on three stacked substrates.

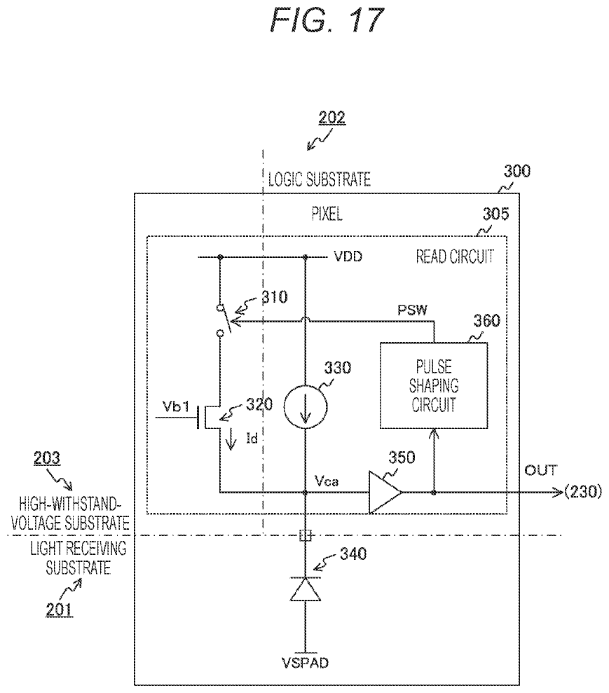

FIG. 17 is a circuit diagram depicting a configuration example of the pixel 300 in the seventh embodiment of the present technology. The pixel 300 of the seventh embodiment is different from that of the first embodiment in that a part of the read circuit 305 is arranged on a high-withstand-voltage substrate 203 and the rest is arranged on the logic substrate 202. For example, the SF cut-off switch 310 and the source follower transistor 320 in the read circuit 305 are arranged on the high-withstand-voltage substrate 203. The rest of the read circuit 305 and its subsequent stage (such as the signal processing section 230) are arranged on the logic substrate 202.

Since elements required to have a high withstand voltage are separated and formed on a wafer corresponding to the high-withstand-voltage substrate 203, a process of the logic substrate 202 optimized for a thin film transistor can be selected. Therefore, it is easy to reduce a pixel size.

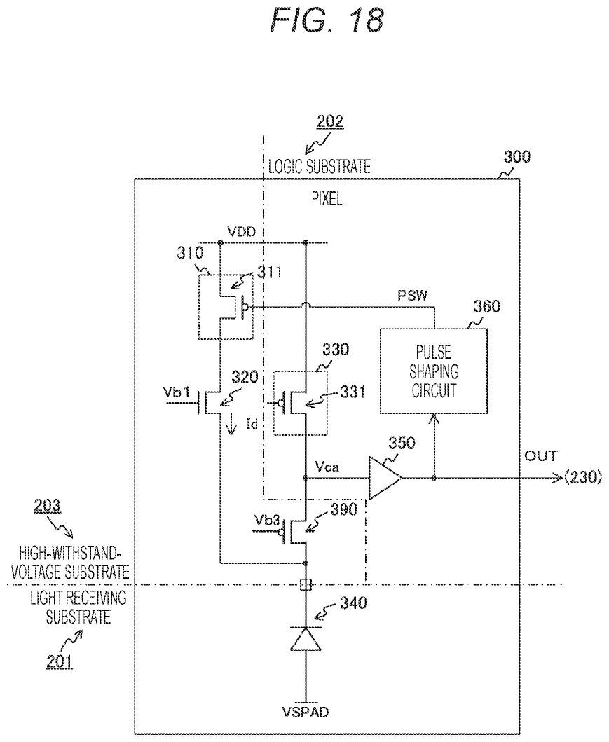

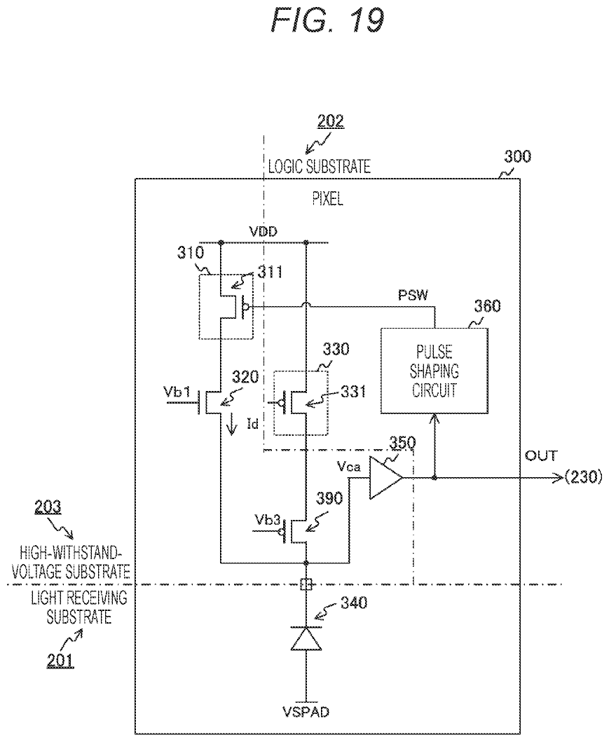

Note that the fourth embodiment and the modified example thereof can also be applied to the seventh embodiment. In a case where the fourth embodiment is applied, the SF cut-off switch 310, the voltage limiting transistor 390, and the source follower transistor 320 in the read circuit 305 are arranged on the high-withstand-voltage substrate 203 as illustrated in FIG. 18. Furthermore, in a case where the modified example of the fourth embodiment is applied, the amplifier 350 is further arranged on the high-withstand-voltage substrate 203 as illustrated in FIG. 19.

In this manner, the process of the logic substrate 202 can be optimized since a part of the read circuit 305 is arranged on the high-withstand-voltage substrate 203 according to the seventh embodiment of the present technology. Therefore, it is easy to reduce a pixel size.

### 8. Eighth Embodiment

Although the current source 330 and the amplifier 350 are connected to the cathode of the SPAD 340 in the first embodiment described above, the current source 330 and the amplifier 350 can also be connected to the anode of the SPAD 340. The solid-state imaging element 200 of an eighth embodiment is different from that of the first embodiment in that connection destinations of an anode and a cathode of the SPAD 340 are changed.

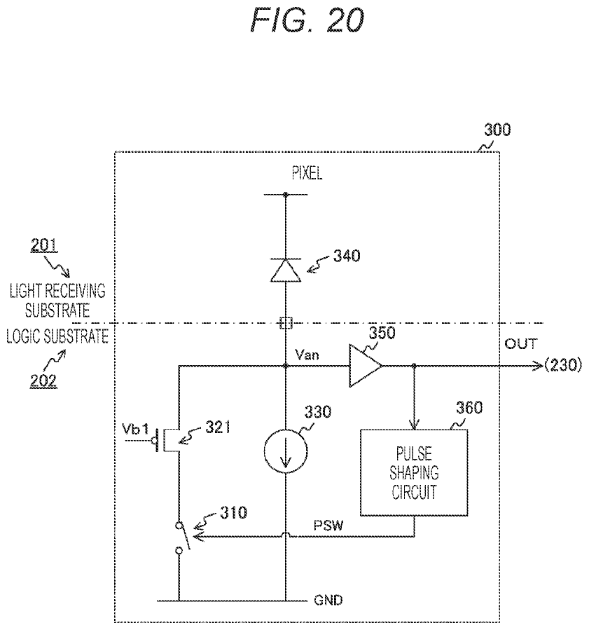

FIG. 20 is a circuit diagram depicting a configuration example of the pixel 300 in the eighth embodiment of the present technology. In the pixel 300 of the eighth embodiment, the cathode of the SPAD 340 is connected to a breakdown voltage and an excess bias voltage. The current source 330 is inserted between the anode of the SPAD 340 and a read circuit ground GND. Furthermore, a pMOS source follower transistor 321 is provided instead of the nMOS source follower transistor 320. The SF cut-off switch 310 opens and closes a path between a drain of the source follower transistor 321 and a negative bias VSPAD according to the pulse signal PSW. The connection illustrated in the drawing enables detection of a photon from a decrease in a voltage of the anode.

Note that the second to seventh embodiments can be applied to the eighth embodiment.

In this manner, the photon can be detected from the decrease in the voltage of the anode since the current source 330 and the amplifier 350 are connected to the anode of the SPAD 340 according to the eighth embodiment of the present technology.

### 9. Example of Application to Mobile Body

The technology according to the present disclosure (present technology) can be applied to various products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a ship, and a robot.

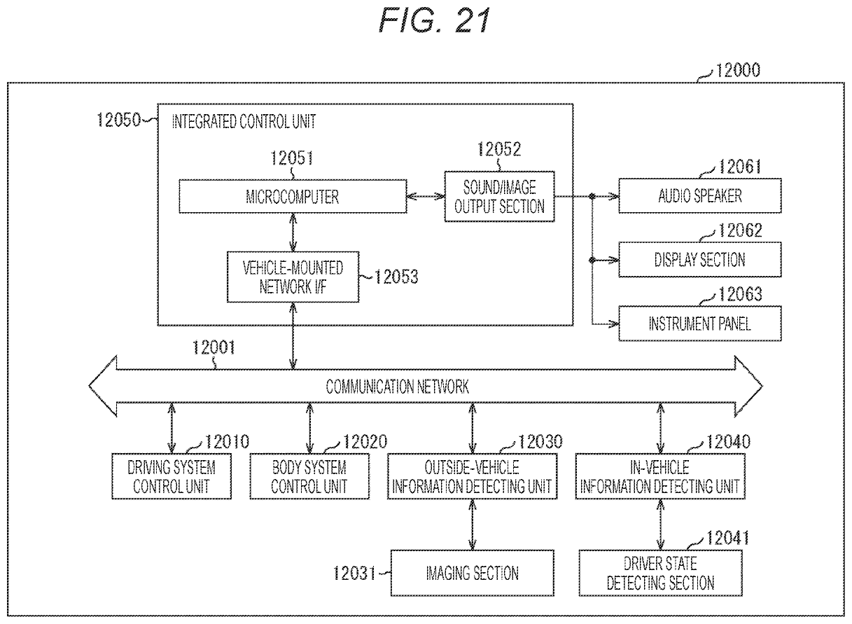

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

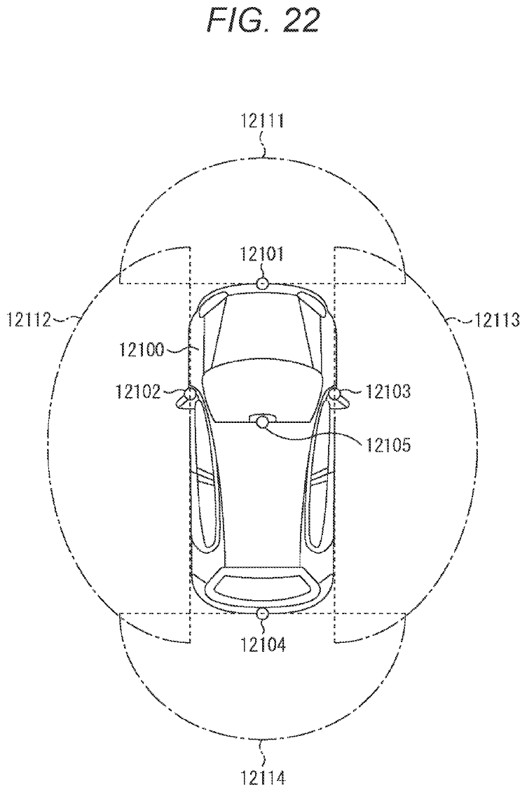

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described as above. The technology according to the present disclosure can be applied to, for example, the imaging section 12031 among the above-described configurations. Specifically, the distance measurement module 100 in FIG. 1 can be applied to the outside-vehicle information detecting unit 12030. It is possible to improve the distance measurement accuracy and enhance the safety of the vehicle control system by applying the technology according to the present disclosure to the outside-vehicle information detecting unit 12030.

Note that the above-described embodiments illustrate examples for embodying the present technology, and the matters in the embodiments respectively have correspondence relationships with the matters specifying the invention in the claims. Similarly, the matters specifying the invention in the claims respectively have correspondence relationships with the matters in the embodiments of the present technology having the same names. However, the present technology is not limited to the embodiments, and can be embodied by making various modified examples to the embodiments within the scope not departing from the gist thereof.

Furthermore, processing procedures described in the above-described embodiments may be regarded as a method including these series of procedures, and may be regarded as a program for causing a computer to execute these series of procedures or a recording medium storing the program. As this recording medium, for example, a compact disc (CD), a mini disc (MD), a digital versatile disc (DVD), a memory card, a Blu-ray (registered trademark) disc, or the like can be used.

Note that the effects described in the present specification are merely examples and are not limited, and there may be additional effects.

Note that the present technology can also have the following configurations.

(1) A light receiving element including:
an avalanche photodiode;
a charging section that causes a constant current to flow between any one terminal of a cathode and an anode of the avalanche photodiode and a predetermined voltage;
a source follower transistor having a source connected to the one terminal;
a logic gate that outputs an output signal on the basis of a comparison result between a voltage of the one terminal and a predetermined reference voltage; and
a source follower cut-off switch that opens and closes a path between a drain of the source follower transistor and the predetermined voltage on the basis of the output signal.

(2) The light receiving element according to (1), in which
the source follower cut-off switch transitions to an open state when the output signal of a predetermined level is output, and transitions to a closed state when a predetermined delay time elapses since the transition to the open state, and
the source follower transistor generates a drain current within a period from when the source follower cut-off switch transitions to the closed state to when the voltage of the one terminal becomes a predetermined cut-off voltage.

(3) The light receiving element according to (1) or (2), in which
a bias voltage within a range from a sum of a threshold voltage of the source follower transistor and the voltage of the one terminal when the source follower cut-off switch transitions from the open state to the closed state to a sum of the reference voltage and the threshold voltage is applied to a gate of the source follower transistor.

(4) The solid-state imaging element according to any one of (1) to (3), further including a voltage limiting transistor that limits an amplitude of a signal input to the logic gate.

(5) The light receiving element according to (4), in which
an input terminal of the logic gate is connected to a connection node between the charging section and the voltage limiting transistor.

(6) The light receiving element according to (4), in which
an input terminal of the logic gate is connected to a connection node between the voltage limiting transistor and the avalanche photodiode.

(7) The light receiving element according to any one of (1) to (6), in which
the predetermined voltage is applied to a gate of the source follower transistor.

(8) The light receiving element according to any one of (1) to (7), further including a distance calculation section that calculates a distance to an object on the basis of a time between a light emission timing of irradiation light from a light emitting source and one timing of falling and rising of the output signal.

(9) The light receiving element according to any one of (1) to (8), in which
the avalanche photodiode, the charging section, the source follower transistor, the logic gate, and the source follower cut-off switch are provided in each of a plurality of pixels.

(10) The light receiving element according to any one of (1) to (9), in which
the avalanche photodiode is provided on a predetermined light receiving substrate, and
the charging section, the source follower transistor, the logic gate, and the source follower cut-off switch are provided on a predetermined logic substrate.

(11) The light receiving element according to any one of (1) to (9), in which
the avalanche photodiode is provided on a predetermined light receiving substrate,
a part of a read circuit including the source follower transistor and the source follower cut-off switch is provided on a predetermined high-withstand-voltage substrate, and
a rest of the read circuit is provided on a predetermined logic substrate.

(12) The light receiving element according to any one of (1) to (11), in which
the charging section includes a current limiting resistor inserted between the predetermined voltage and the one terminal.

(13) The light receiving element according to any one of (1) to (12), further including
a charging section cut-off switch that opens and closes a path between the charging section and the predetermined voltage on the basis of the output signal.

(14) The light receiving element according to any one of (1) to (13), further including
a pulse shaping circuit that outputs a pulse signal of a first logic level for setting the source follower cut-off switch in the open state over a period until a predetermined delay time elapses since any timing of falling and rising of the output signal, in which
the source follower cut-off switch transitions to the open state in a period in which the pulse signal is at the first logic level, and transitions to the closed state in a period in which the pulse signal is at a second logic level different from the first logic level.

(15) The light receiving element according to any one of (1) to (13), further including
a pulse shaping circuit that outputs a pulse signal of a first logic level for setting the source follower cut-off switch in the closed state over a period of a pulse width when a predetermined delay time elapses since any timing of falling and rising of the output signal, in which
the source follower cut-off switch transitions to the open state in a period in which the pulse signal is at a second logic level different from the first logic level, and transitions to the closed state in a period in which the pulse signal is at the first logic level.

(16) The light receiving element according to any one of (1) to (15), in which
the one terminal is the cathode,
the predetermined voltage is a power supply voltage, and
the charging section supplies the constant current from the power supply voltage to the cathode.

(17) The light receiving element according to any one of (1) to (15), in which
the one terminal is the anode,
the predetermined voltage is a read circuit ground, and
the charging section supplies the constant current from the anode to the read circuit ground.

(18) A distance measurement module including:
an avalanche photodiode;
a charging section that causes a constant current to flow between any one terminal of a cathode and an anode of the avalanche photodiode and a predetermined voltage;
a source follower transistor having a source connected to the one terminal;
a logic gate that outputs an output signal on the basis of a comparison result between a voltage of the one terminal and a predetermined reference voltage;
a source follower cut-off switch that opens and closes a path between a drain of the source follower transistor and the predetermined voltage on the basis of the output signal; and
a signal processing section that processes the output signal.

(19) A distance measurement system including:
an illumination device that emits irradiation light; and
a light receiving element that receives reflected light with respect to the irradiation light, in which
the light receiving element includes:
an avalanche photodiode;
a charging section that causes a constant current to flow between any one terminal of a cathode and an anode of the avalanche photodiode and a predetermined voltage;
a source follower transistor having a source connected to the one terminal;
a logic gate that outputs an output signal on the basis of a comparison result between a voltage of the one terminal and a predetermined reference voltage; and
a source follower cut-off switch that opens and closes a path between a drain of the source follower transistor and the predetermined voltage on the basis of the output signal.

(20) A method for controlling a light receiving element including:
a charging procedure of causing a constant current to flow between any one terminal of a cathode and an anode of an avalanche photodiode and a predetermined voltage;
an output procedure of outputting an output signal on the basis of a comparison result between a voltage of the one terminal and a predetermined reference voltage; and
a source follower cut-off procedure of opening and closing a path between a drain of a source follower transistor whose source is connected to the voltage of the one terminal and the predetermined voltage on the basis of the output signal.

### REFERENCE SIGNS LIST

100 Distance measurement module
110 Light emitting source
120 Timing generation section
200 Solid-state imaging element
201 Light receiving substrate
202 Logic substrate
203 High-withstand-voltage substrate
210 Control circuit
220 Pixel array section
230 Signal processing section
231 TDC
232 Distance calculation section
300 Pixel
305 Read circuit
310 SF cut-off switch
311, 331, 381 pMOS transistor
320, 321 Source follower transistor
330 Current source
340 SPAD
350 Amplifier
360 Pulse shaping circuit
370 Current limiting resistor
380 Current source cut-off switch
390 Voltage limiting transistor
12030 Outside-vehicle information detecting unit

1. A light receiving element comprising:
an avalanche photodiode;
a charging section that causes a constant current to flow between any one terminal of a cathode and an anode of the avalanche photodiode and a predetermined voltage;
a source follower transistor having a source connected to the one terminal;
a logic gate that outputs an output signal on a basis of a comparison result between a voltage of the one terminal and a predetermined reference voltage; and
a source follower cut-off switch that opens and closes a path between a drain of the source follower transistor and the predetermined voltage on a basis of the output signal.

2. The light receiving element according to claim 1, wherein
the source follower cut-off switch transitions to an open state when the output signal of a predetermined level is output, and transitions to a closed state when a predetermined delay time elapses since the transition to the open state, and
the source follower transistor generates a drain current within a period from when the source follower cut-off switch transitions to the closed state to when the voltage of the one terminal becomes a predetermined cut-off voltage.

3. The light receiving element according to claim 1, wherein
a bias voltage within a range from a sum of a threshold voltage of the source follower transistor and the voltage of the one terminal when the source follower cut-off switch transitions from the open state to the closed state to a sum of the reference voltage and the threshold voltage is applied to a gate of the source follower transistor.

4. The light receiving element according to claim 1, further comprising a voltage limiting transistor that limits an amplitude of a signal input to the logic gate.

5. The light receiving element according to claim 4, wherein
an input terminal of the logic gate is connected to a connection node between the charging section and the voltage limiting transistor.

6. The light receiving element according to claim 4, wherein
an input terminal of the logic gate is connected to a connection node between the voltage limiting transistor and the avalanche photodiode.

7. The light receiving element according to claim 1, wherein
the predetermined voltage is applied to a gate of the source follower transistor.

8. The light receiving element according to claim 1, further comprising a distance calculation section that calculates a distance to an object on a basis of a time between a light emission timing of irradiation light from a light emitting source and one timing of falling and rising of the output signal.

9. The light receiving element according to claim 1, wherein
the avalanche photodiode, the charging section, the source follower transistor, the logic gate, and the source follower cut-off switch are provided in each of a plurality of pixels.

10. The light receiving element according to claim 1, wherein
the avalanche photodiode is provided on a predetermined light receiving substrate, and
the charging section, the source follower transistor, the logic gate, and the source follower cut-off switch are provided on a predetermined logic substrate.

11. The light receiving element according to claim 1, wherein
the avalanche photodiode is provided on a predetermined light receiving substrate,
a part of a read circuit including the source follower transistor and the source follower cut-off switch is provided on a predetermined high-withstand-voltage substrate, and
a rest of the read circuit is provided on a predetermined logic substrate.

12. The light receiving element according to claim 1, wherein
the charging section includes a current limiting resistor inserted between the predetermined voltage and the one terminal.

13. The light receiving element according to claim 1, further comprising
a charging section cut-off switch that opens and closes a path between the charging section and the predetermined voltage on a basis of the output signal.

14. The light receiving element according to claim 1, further comprising
a pulse shaping circuit that outputs a pulse signal of a first logic level for setting the source follower cut-off switch in the open state over a period until a predetermined delay time elapses since any timing of falling and rising of the output signal, wherein
the source follower cut-off switch transitions to the open state in a period in which the pulse signal is at the first logic level, and transitions to the closed state in a period in which the pulse signal is at a second logic level different from the first logic level.

15. The light receiving element according to claim 1, further comprising
a pulse shaping circuit that outputs a pulse signal of a first logic level for setting the source follower cut-off switch in the closed state over a period of a pulse width when a predetermined delay time elapses since any timing of falling and rising of the output signal, wherein
the source follower cut-off switch transitions to the open state in a period in which the pulse signal is at a second logic level different from the first logic level, and transitions to the closed state in a period in which the pulse signal is at the first logic level level.

16. The light receiving element according to claim 1, wherein
the one terminal is the cathode,
the predetermined voltage is a power supply voltage, and
the charging section supplies the constant current from the power supply voltage to the cathode.

17. The light receiving element according to claim 1, wherein
the one terminal is the anode,
the predetermined voltage is a read circuit ground, and
the charging section supplies the constant current from the anode to the read circuit ground.

18. A distance measurement module comprising:
an avalanche photodiode;
a charging section that causes a constant current to flow between any one terminal of a cathode and an anode of the avalanche photodiode and a predetermined voltage;
a source follower transistor having a source connected to the one terminal;
a logic gate that outputs an output signal on a basis of a comparison result between a voltage of the one terminal and a predetermined reference voltage;
a source follower cut-off switch that opens and closes a path between a drain of the source follower transistor and the predetermined voltage on a basis of the output signal; and
a signal processing section that processes the output signal.

19. A distance measurement system comprising:
an illumination device that emits irradiation light; and
a light receiving element that receives reflected light with respect to the irradiation light, wherein
the light receiving element includes:
an avalanche photodiode;
a charging section that causes a constant current to flow between any one terminal of a cathode and an anode of the avalanche photodiode and a predetermined voltage;
a source follower transistor having a source connected to the one terminal;
a logic gate that outputs an output signal on a basis of a comparison result between a voltage of the one terminal and a predetermined reference voltage; and
a source follower cut-off switch that opens and closes a path between a drain of the source follower transistor and the predetermined voltage on a basis of the output signal.

20. A method for controlling a light receiving element comprising:
a charging procedure of causing a constant current to flow between any one terminal of a cathode and an anode of an avalanche photodiode and a predetermined voltage;
an output procedure of outputting an output signal on a basis of a comparison result between a voltage of the one terminal and a predetermined reference voltage; and
a source follower cut-off procedure of opening and closing a path between a drain of a source follower transistor whose source is connected to the voltage of the one terminal and the predetermined voltage on a basis of the output signal.
